(19) United States
(12) Patent Application Publication
(10) Pub. No.: US 2010/0282165 A1
(43) Pub. Date: Nov. 11, 2010

(54) PRODUCTION OF ADJUSTMENT STRUCTURES FOR A STRUCTURED LAYER DEPOSITION ON A MICROSYSTEM TECHNOLOGY WAFER

(75) Inventor: Roy Knechtel, Geraberg (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: X-FAB SEMICONDUCTOR FOUNDRIES AG, Erfurt (DE)

(21) Appl. No.: 12/664,582

(22) PCT Filed: Jun. 16, 2008
(86) PCT No.: PCT/EP2008/057578

§ 371 Date: May 21, 2010

(30) Foreign Application Priority Data
Jun. 14, 2007 (DE) 10 2007 027 434.5

(51) Int. Cl. C23F 1/00; C23C 16/00

(52) U.S. Cl. 118/721; 216/99; 216/67

(57) ABSTRACT

The invention relates to a method for selective material deposition for sensitive structures in micro systems technology for producing mechanical adjustment structures (6, 5) for a vapour penetration mask (8), the adjustment structures on the component disc (7) and the mask being created using the same structuring method. Complementary adjustment structures can be produced thereon with a very high degree of precision. KOH etching in silicon can be used in order to create equally inclined flanks (2, 2a) in a depression and a complementary protrusion.

### CROSS-REFERENCE TO RELATED APPLICATIONS

The application is a U.S. National Stage Application of International Application of PCT/EP2008/057578 filed Jun. 16, 2008, which claims the benefit of German Patent Application No. 10 2007 027 434.5 filed Jun. 14, 2007, the disclosures of which are herein incorporated by reference in their entirety.

### FIELD OF THE DISCLOSURE

The invention relates to a method for producing adjustment structures fort the structured layer deposition on a wafer of the micro system technology. For this purpose, a vapour penetration mask is used through which layers or layer portions may be deposited in a raised way. Other fabrication methods are also included as well as a set of components (kit of parts) which are adapted for cooperation.

### BACKGROUND OF THE DISCLOSURE

It is frequently necessary in wafer processes of the micro system technology that, during progression or at the end of the fabrication of complex micro electromechanical structures, the semiconductor discs (wafer) or the chip structures, respectively, are provided in part (structured or selective) with layers. Therein, the classical multi layer technology which is based on the deposition of the layer over the whole area and its subsequent, photochemical structuring, cannot be used since either certain partial areas of the wafer/chip are not at all permitted to be coated (for example, such layers can render micro mechanical structures inoperative) and/or a photo chemical structuring is not possible (surface profile, not etchable layers) or the effort is to big.

Vapour penetration masks are known for a long time, which comprise openings for the material to be deposited. Such masks, for example out of metal, are problematic since, with respect to highly profiled surfaces, misalignments are encountered and the (selective) structures to be deposited, are not exactly delimited thereby. Disadvantages related to quality, yield and packing density come up in this way. The poor adjustability of such hard masks with micro structures has the same disadvantageous effect.

It is an object of the invention to improve the precision of the deposition of structured layers on processed micro system technology wafers.

### SUMMARY OF THE DISCLOSURE

The object is achieved by means of a method for producing adjustments structures for a selective deposition of material on a wafer of the micro system technology using a vapour penetration mask.

In the method, two or more protruded or depressed wafer adjustment structures are produced on the micro system technology wafer using a defined structuring technology (claim 1). Two or more protruded or depressed mask adjustment structures are also produced on a mask disc which comprises the same diameter as the micro system technology wafer. The defined structuring technology is used. Vapour penetration is openings are formed in the mask disc in order to produce the vapour penetration mask. The vapour penetration openings are adapted to leave defined areas of the micro system technology wafer open (or accessible) when the mask—for example in a self adjusting way—is put onto the wafer. The adjustment is effected through—complementary—adjustment elements on the wafer or the mask respectively.

The inventive method can, therefore, produce a suitable vapour penetration mask which enables a structured layer deposition on the component disc (in short “wafer”) with self adjusting properties upon a mechanical coupling of the adjustment structures and the mask adjustment structures such that the deposition can be effected through the wafer penetration openings which leaves open the areas of the component disc to be coated and which covers the areas which are not to be coated whereby a precise position adjustment of the wafer penetration openings is defined by means of the adjustment structures of the wafer and the mask adjustment structures.

The preciseness of the position adjustment is achieved in that the production of the adjustment structures on the component disc and the mask adjustment structures on the vapour penetration mask is made by means of the same structuring method such that, because of the equal diameter of those substrates, relatively uniform processing conditions are present which, therefore, contribute to a precise shaping and positioning of the respective adjustment structures.

Because of the equal diameters, a suitable handling of the system out of wafer and vapour penetration mask can be achieved during the processing procedure.

Also a method for the selective material deposition (claim 21) is proposed on a micro system technology wafer using a vapour penetration mask and with adjustment structures between the wafer of the micro system technology and the mask. It comprises the formation of at least two adjustment structures on the micro system technology wafer using a defined structuring technology. Furthermore, at least two substantially complementary mask adjustments structures are formed on a mask disc which comprises the same diameter as the wafer of the micro system technology whereby the formation of the adjustments structures is affected using the same structuring technology. Vapour penetration openings are formed in the mask disc for forming the vapour penetration mask. Upon self adjusting positioning of the vapour penetration mask on the wafer of the micro system technology, the vapour penetration openings leave defined areas of the wafer open for a selective material deposition on the micro system technology wafer through the vapour penetration openings of the mask. This is also affected then.

The kit of parts (set out of components, claim 24) also proposed, consists out of a micro system technology wafer and a vapour penetration mask which are adapted to each other and provided for (highly) accurate, selective material deposition by means of adjustment structures on the vapour penetration mask and the micro system technology wafer. At least two protruding or depressed adjustment structures are provided on the micro system technology wafer generated using a predefined structuring technology. At least two essentially complementary, protruding or depressed mask adjustment structures are arranged on a mask disk which has the same diameter as the micro system technology wafer. The fabrication is affected using the predefined structuring technology. Vapour penetration openings are provided in the mask disc in order to produce the vapour penetration mask. The vapour penetration openings allow to open defined areas of the micro system technology wafer for the selective material deposition.

In further, advantageous embodiments, the predefined structuring technology may comprise a time controlled potassium hydroxide etching of silicon which is used as starting material for the component disc and the vapour penetration opening. Because of a special crystallographic orientation, for example a [100] orientation, an anisotropic etching characteristic is affected as is known, such that flank inclination angles of an exactly defined value can be achieved for protrusions and depressions such that a precise sliding movement one with respect to the other of the respective inclined surfaces upon the mechanical adjustment of the device wafer and the vapour penetration mask.

In further advantageous embodiments, the silicon material is again chosen as base material for the device wafer and also for the vapour penetration mask, wherein the respective adjustment structures are produced using a plasma chemical etching method such that, also because of the nearly identical processing conditions, very similar dimensions for the complementary structures on the device wafer and the vapour penetration mask are resulting. Also thereby, a very accurate adjustment of the vapour penetration mask relative to the device wafer is assured.

In further advantageous embodiments, a glass disc is selected as starting material for the vapour penetration mask which glass disc can then be structured, because of the similar properties with respect to the surface roughness, planarity and the like, using a plasma mechanical etching which is used in the same way also for the device wafer such that a high degree of precision in producing the complementary adjustment structures is also resulting in this embodiment.

In further embodiments, a combination disc out of silicon and glass serves as a starting material for the vapour penetration mask.

By means of the inventive production of the first adjustment structures and the second mask adjustment structures (on the wafer or the mask, respectively), the formation of the special structures for the vapour penetration mask and the micro system technology wafer is achieved such that an accurate and stable position of the vapour penetration mask is achieved by interaction during the process of deposition.

Because of the high precision in producing the complementary adjustment structures, not only a very precise adjustment of the areas not to be coated, and the areas on the component disc (wafer) to be coated, is resulting, but these can also reliably separated from each other after the deposition process without undesired mechanical action on the device wafer and the vapour penetration mask being affected. The vapour penetration mask can, thereby, be used for many component discs.

Further advantageous embodiments are presented in the further dependent patent claims and are clearly apparent from the following description.

In a modification, a method for self adjusting adjustment structures for a structured layer deposition on a wafer of the micro system technology using a deposition mask or a vapour penetration mask, respectively, is provided whereby the deposition is affected through openings in a vapour penetration mask placed on the wafer and adapted for multiple usage which mask covers the areas of the wafer not to be coated, and the accurate positional adjustment is affected by means of the adjustment structures. The method is characterized thereby that the adjustment structures are produced on the deposition mask as structures protruding from the surface and on the micro system technology wafer as structures depressed with respect to the surface accurately fitting to each other such that the structures engage with each other during the deposition and are adapted to be separated again after the deposition.

In a further modification, a method for self adjusting adjustment structures for a structured layer deposition on a micro system technology wafer using a deposition mask or a vapour penetration mask, respectively, is provided whereby the deposition is affected through openings in a vapour penetration mask placed on the wafer and being adapted for multiple use which mask covers the areas of the wafer not to be coated, and an accurate positional adjustment is affected through the adjustment structures. The method is characterized in that the adjustment structures are produced on the deposition mask as structures depressed in the surface and on the wafer of micro system technology as structures protruded with respect to the surface (exactly) fitting to each other such that the structures engage within each other during the deposition and are adapted to be separated after the deposition.

The height of the structures is provided such that no burden or hindrance is affected during adjustment. The kit of parts (claim 28) preferably has flank inclination ankles which comprise an inclination between 50° and 70°. Juxtaposed inclined flanks of the mask and the wafer are adjusted with respect to the inclination to each other in the adjustment elements. In case of a KOH etching of the flanks, an inclination of 54, 74° is resulting.

The invention is now further explained and supplemented with reference to embodiments using the drawings.

### BRIEF DESCRIPTIONS OF THE DRAWINGS

In the Figures:

FIG. 1a shows schematically a vertical section of a vapour penetration mask 8 and a component disc as wafer 7 having corresponding adjustment structures 5, 6 or 5′, 6′ prior to using them in order to define a relative position of the vapour penetration mask and the component disc by means of a contact of the adjustment structures,

FIG. 1b, 1c show a top view or a section view, respectively, of an inventive adjustment structure which is produced by a KOH etching of a (100) silicon disc, wherein the adjustment structure is provided on the micro system technology disc in the shape of a pyramidal (pyramid shaped) depression without tip,

FIG. 1d, 1e show a top view or a section view, respectively, of a mask adjustment structure according to an example of the invention whereby also a (100) silicon disc is used as a base material for the vapour penetration opening,

FIG. 2 shows schematically a section view of a detail of the combined adjustment components according to FIGS. 1b to 1e,

FIG. 3a, 3b, 3c show corresponding section views of a further area of wafer adjustment structures and mask adjustment structures which are produced by a plasma mechanical etching, wherein FIG. 3a is a section view of an adjustment structure shape of a depression, FIG. 3b is a section view of the mask adjustment structure in the shape of a protrusion and FIG. 3c shows the adjustment components in an assembled arrangement (position).

### DETAILED DESCRIPTION OF THE EMBODIMENTS

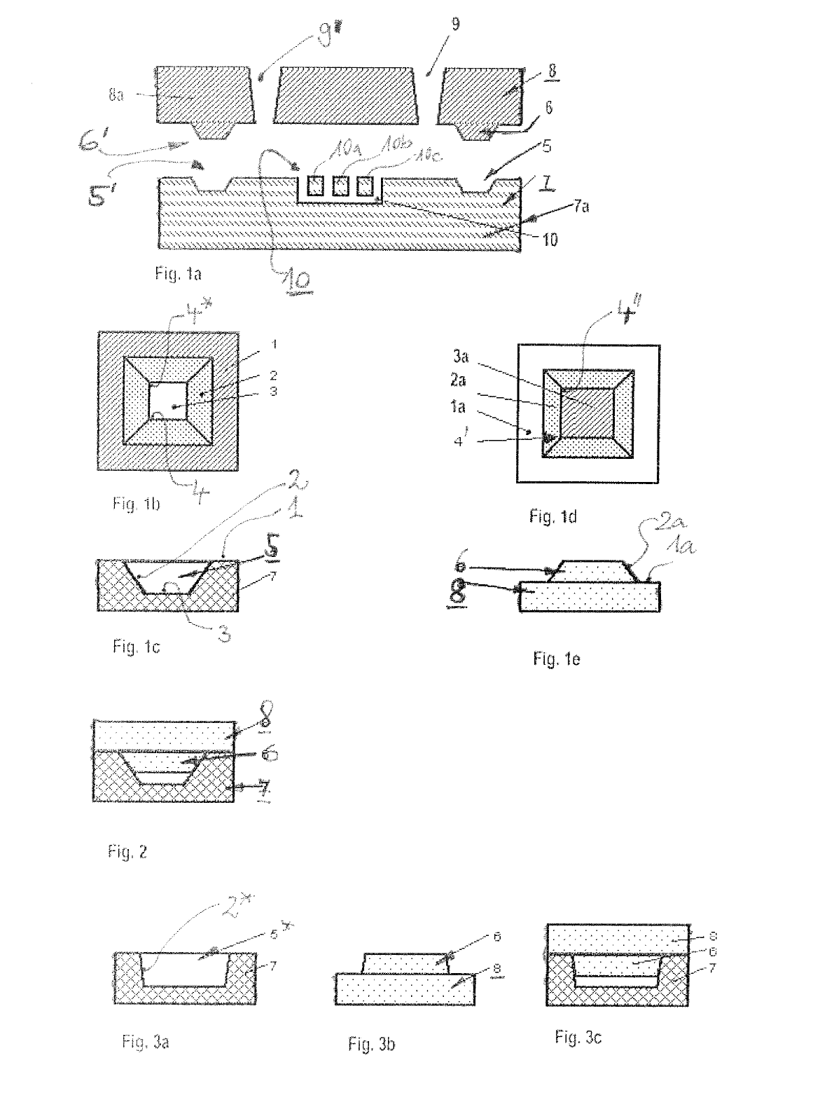

FIG. 1a shows a section view of a micro system technology wafer 7 which comprises device elements 10a, 10b, 10c, for example as sensible structures 10a, 10b, 10c like MEMS or the like. Furthermore, two or more adjustment structures 5, 5′, for example as depressions in a substrate disc 7a, are provided. A vapour penetration mask 8 which is provided with vapour penetration openings 9, 9′, leaves certain areas of the wafer 7 free on which a material is to be selectively deposited without exposing one or several sensible areas 10, for example the element 10a, to the deposition atmosphere.

In the embodiments shown, the vapour penetration mask 8 is also produced from a silicon disc which comprises complementary mask adjustment structures 6 corresponding to the adjustment structures 5 and which, thereby, are formed as protrusions. On the other side next to the sensitive area 10 are adjustment structures 5′, 6′.

It has to be noted that in the described embodiments, also the adjustment structures 5 of the wafer 7 can be provided as protrusions and the mask adjustment structures 6 in the vapour penetration mask can be provided as depressions.

In an embodiment, the discs 8a and 7a are formed out of silicon having a (100) surface orientation. The wafer 7 of the micro system technology as well as the vapour penetration mask 8 are produced on the basis of a (100) Si disc whereby a high accuracy during production of the adjustment structures by etching steps may be achieved, the etching rate of which depends on the crystallographic orientation.

In general, methods of the micro system technology are used for achieving a high accuracy of the position of the vapour penetration mask and the structure layout (the arrangement or placing of the vapour penetration openings 9, 9′ or the vapour penetration openings in the micrometer range, respectively). Unstructured wafers out of silicon or glass are used as starting raw material pieces for the vapour penetration mask since those may be processed by the above mentioned methods and provide the best possible conditions with respect to thickness, thickness deviation, planarity and surface quality. Furthermore, they may be adapted to the process applications in their size.

The openings 9, 9′ are, in an implementation, provided individually and not interconnected or are to be seen, in another implementation, to be continuous as a continuous opening, for example a circular ring or square. There are at least several openings in a mask 8 and several sensible areas 10 on the wafer such that the plural of “openings” is also valid for further openings which are not separately shown.

Essentially the same diameter as with the system wafer 7 which is to be provided with a deposition is used. In principle, all methods are suitable with which the vapour penetration through-openings 9 and the mechanical adjustment structures 5 and the mask adjustment structures 7 may be produced very accurately. Therein, it is provided in advantageous embodiments that the corresponding, mechanical adjustment structures 5, 6 or 5′, 6′ of the system and the deposition mask wafer 7a, 8a are produced with the same technology in order to achieve an accurate alignment. The vapour penetration openings 9 may however be also produced with another technology if required. At least two of the adjustment structures 5, 6 are provided on each of the wafer surfaces 7a, 8a in order to enable an accurate adjustment in the X- and Y-direction as well as in the angular direction. More than two structures put up the adjustment ability and accuracy and prevent a possible shifting after alignment.

FIGS. 1b and 1c show a top view or a section view, respectively, of a section of the wafer 7. As is shown, the adjustment structure 5 is provided in the shape of a pyramid shaped depression in one surface 1 of the disc 7a, wherein the etched slopes 2 which represent the crystallographic surfaces, are narrowing down and are ending in a deeply etched area 3 which is flat. The pyramid has no tip here but is a stub such.

FIGS. 1d and 1e show a top view or a section view, respectively, of a section of the vapour penetration mask 8. As is shown, the adjustment structure 6 is provided in the shape of a pyramid shaped protrusion on one surface la of the disc 8a, wherein etched slopes 2 which represent the crystallographic surfaces, are narrowing down and are ending in an area 3 which is positioned at a higher level and is flat. The pyramid has no tip here but is a stub such.

In this embodiment, the same accurate alignment of the azimuthal crystallographic orientation of the crystal wafer 7a, 8a is used which is characterized each by an engagement edge provided on each wafer and being crystallographic orientated. Upon the processing of the disc 7a, 8a, the production of the adjustment structures 5, 5′ and 6′, 6 in the identical, horizontal orientation of the disc 7a, 8a is used such that the flanks 2, 2a are produced as identical, crystallographic surfaces.

It is a matter of course that etching masks exactly adjusted to each other with respect to geometry and position, are used in the production of the adjustment structures. Hard masks out of an oxide nitride double layer are used for etching whereby the oxide is applied to the silicon and the nitride is provided as upper layer, whereupon this mask is photo chemically structured. The etching is affected in a time controlled manner such that the hole depths (the depression of the area 3) and the height of the protrusion (the height of the area 3a) may be exactly adjusted to each other.

The etching rate for many process recipes is known or can be determined efficiently by experiment. Multiple etching is possible whereby the possibility of an improved control of the process output is resulting.

In an embodiment, crystallographically caused surfaces, for example the flanks 2, 2a, are formed by a KOH etching (potassium hydroxide) of single crystal silicon. The inclined surfaces 2 of the holes or depressions 3, respectively, of the adjustment structures 5 and the inclined surfaces 2a of the protruding part 3a of the mask adjustment structures 6, thereby have the same inclination angle of preferably 54, 74°.

The inclination angles of the outer corners 4 are protected during etching with compensation structures. Since crystallographic planes which may be etched faster, are located at the corners 4, 4* or 4′, 4″, structures of the angular or tongue type are preferably arranged on these in the etching mask which structures are under-etched but is slow down the etching of the corners in spite of this so much that rectangular or only slightly rounded corners are resulting in the end.

The stamps or protrusions 3a, respectively, fit exactly into each other with a high precision in case of an accurate design of the etching masks for the production of the adjustment structures 6, since the hole 3 and the stamp 3a are conical and thereby allow a good fitting. A control of the etching processes for the adjustment structures 5, 6 can suitably be affected by computer supported methods for determining the size of the masks and by simulation of etching.

FIG. 2 shows the vapour penetration mask 8 and the wafer 7 in an assembled condition. The conical structures produced by means of the exactly controlled etching process and having a high precision, thereby have a good affect of self adjustment since the flanks 2, 2a are centring themselves even in case of a lateral offset during the assembly. In order to avoid stress or striking, respectively, upon assembly, the protruding mask adjustment structure 5 is formed in a demonstrative embodiment such that they do not touch the base 3 of the depression 5. This has the consequence that the masks may be used again very often because of the low mechanical burden.

The structures shown in FIG. 3, relate also to silicon wafers.

In FIG. 3a, the adjustment structure 5* is shown in the shape of a depression wherein the flanks 2* may be adjusted according to the etching conditions.

FIG. 3b shows the vapour penetration mask 8 with the complementary mask adjustment structure 6.

FIG. 3c shows the vapour penetration mask and the wafer 7 in an assembled condition wherein also here the protrusion of the adjustment structure 6 does not reach to the bottom of the depression 5 in the shown embodiment in order to improve the assembling procedure as is also described above.

Upon the production of the adjustment structures shown in FIG. 3, plasma mechanical silicon etching, such as advanced silicon etching, BOSCH-process, are used. With these etching processes, it is possible to produce vertical and also slightly conical structures in silicon which may serve as adjustment structures 5 and 6. The latter is achieved by means of a process modification. The conical structures 5, 6 are better adapted for assembling. The crystallographic orientation does not play a part here. No corner compensation structures are used. A simple etch mask design is concerned.

Round and multi corner structures are possible. A resist mask is sufficient for etching.

The adjustment structures can also be produced by means of sandblasting on glass, silicon or combination wafers out of these materials. For this purpose, a hard mask is used. The positioning accuracy is, however, not as high as with the etch embodiments. In other embodiments, also micro drilling and micro machining is used. A hard mask is not necessary for this purpose. The achievable accuracy is high when using a CNC process.

The four above described processes may be used also for realizing the vapour penetration holes 9, 9′, wherein the KOH etching is again a very advantageous modification since it is economical and the conical holes 9 are very advantageous for the vapour deposition since the vapour is guided into the hole 9. Suitable vapour penetration holes 9 may, however, also realized by other technologies. In principle, the technologies for the hole structures 9, 9′ and the adjustment structures 5, 6, 5′, 6′ may be combined arbitrarily. With respect to the efficiency of the process, it is advantageous to use the same processes. In case mask processes are used for the structuring of the adjustment structures 6 and the vapour penetration openings 9, it is advantageous when the masks are applied to both sides of the mask wafer 8a prior to the first etching. However, it is also conceivable that the etching steps are carried out sequentially from one side thereof.

It is to be noted that also adjustment structures 5 on the wafer 7 may be provided as protrusions and the mask adjustment structures 6 in the vapour penetration mask may be provided as depressions in the embodiments described.

In modifications, methods for self-adjusting adjustment structures for a structured layer deposition on a micro system technology wafer using a deposition mask or a vapour penetration mask, respectively, is provided wherein the deposition is affected through openings in a vapour penetration mask to be put onto the wafer and adapted for multiple use which covers the areas of the wafers not to be coated and are reached an accurate position adjustment is effected through the adjustment structures. The method is characterized in that the adjustment structures are produced on the deposition mask as structures protruding from the surface and on the micro system technology wafer as structures lowered with respect to the surface or vice versa, are produced as exactly fitting to each other, such that the structures engage into each other during the deposition and are adapted to be separated again after deposition.

### REFERENCE SIGNS (EXCERPT)

(The same reference signs for the same elements in different Figures)

1 surface or bottom, respectively, of the depression

1a surface of the protrusion

2 etched flank (crystallographic surface) of the adjustment structure of the wafer

2a etched flank (crystallographic surface) of the vapour penetration mask

3 deeply etched area

3a surface of the protruded area

4 location of the compensation structures

5, 5′ adjustment structure, for example in the shape of an adjustment depression

6, 6′ mask adjustment structure, for example in the form of a protrusion

7 micro system technology wafer

7a base disc (for example silicon)

8 vapour penetration mask

8a base disc (for example silicon)

9, 9′ vapour penetration openings

10 device element structure area

10a, 10b, 10c devices (MEMS)

1. Method for producing adjustment structures for a selective material deposition on an micro system technology wafer using a vapour penetration mask, comprising the steps:
producing two or more protruded or depressed adjustment structures on the micro system technology wafer using a predefined structuring technology;
producing two or more protruded or depressed mask adjustment structures on a mask disc which has the same diameter as the micro system technology, using the predefined structuring technology;
forming vapour penetration openings in the mask disc which leave defined areas of the micro system technology wafer freely accessible to the selective material deposition.

2. Method according to claim 1, wherein the vapour penetration mask and the micro system technology wafer consists out of (100)-orientated silicon discs, and the adjustment structures and the mask adjustment structures are produced by KOH etching.

3. Method according to claim 1, wherein the vapour penetration mask and the micro system technology wafer consists out of silicon discs and the adjustment structures and the mask adjustment structures are produced by plasma mechanical silicon etching.

4. Method according to claim 1, wherein the vapour penetration mask consists out of glass, and the adjustment structures and the mask adjustment structures are produced by plasma chemical etching.

5. Method according to claim 1, wherein the vapour penetration mask consists out of glass, and the adjustment structures and the mask adjustment structures are produced by micro milling.

6. Method according to claim 1, wherein the vapour penetration mask consists out of glass, and the adjustment structures and the mask adjustment structures are produced by micro boring.

7. Method according to claim 1, wherein the vapour penetration mask consists out of glass, and the adjustment structures and the mask adjustment structures are produced by sandblasting and using hard masks.

8. Method according to claim 1, wherein the vapour penetration mask consists out of a combination disc assembled out of glass and silicon, and the adjustment structures and the mask adjustment structures are produced by at least one of plasma chemical etching, micro milling, micro boring, and sandblasting and using hard masks.

9. Method according to claim 1, wherein the vapour penetration mask consists out of a combination disc put together out of glass and silicon, and the adjustment structures and the mask adjustment structures are produced by at least one of KOH etching, plasma mechanical silicon etching, plasma chemical etching, micro milling, micro boring, and sandblasting and using hard masks.

10. Method according to claim 1, wherein the two or more mask adjustment structures are produced as protruded structures in a surface ) of the side facing the micro system technology wafer, of a silicon disc forming the vapour penetration mask by means of a mask process using a hard mask on the front side and a hard mask on the back side.

11. Method according to claim 11, wherein the hard mask consists out of a double layer of oxide-nitride, and wherein the mask adjustment structures are produced in an KOH etching, wherein the silicon disc comprises (100)—orientation, and wherein the mask adjustment structures are applied with their straight edges azimuthally crystallographically orientated such that pyramid-like protrusions having slope angles of 54,74 card are forming upon time controlled KOH etching on the side facing the micro system technology wafer and the vapour penetration openings are forming starting from the side facing away from the micro system technology wafer.

12. Method according to claim 11, wherein the inclination angles of the outer corners of the pyramid-like protrusions are protected during etching by means of compensation structures.

13. Method according to claim 11, wherein the production of the adjustment structures corresponding to the mask adjustment structure of the vapour penetration mask in position and size, in the micro system technology wafer is made by KOH etchings of depressions starting from the surface to be provided with a deposition, with a corresponding masking step and the same crystallographic orientation and the same etching method as with the vapour penetration mask.

14. Method according to claim 1, wherein the production of the mask adjustment structures on a facing side of the silicon disc as protruding structures by means of a mask process using an etching mask on the front side and an etching mask on the back side, and a subsequent plasma chemical etching, whereby by means of a time controlled etching on the side facing the micro system technology wafer, cone-shaped protrusions and starting from the side facing away from the micro system technology wafer, the vapour penetration openings are forming.

15. Method according to claim 14, wherein for producing the adjustment structures corresponding to the mask adjustment structures of the vapour penetration mask in position and size, in the micro system technology wafer, depressions are formed by etching starting from the surface to be provided with a deposition with a corresponding masking step and with the same plasma mechanical etching method as the vapour penetration mask.

16. Method according to claim 1, wherein the production of the at least two structures is affected from the surface of the side facing the micro system technology wafer of the vapour penetration mask in a glass disc as protruding structures by means of a mask process using an etching mask on the front side and an etching mask on the back side and a subsequent plasma mechanical etching, whereby cone-shaped protrusions are forming by means of a time controlled etching of the side facing the micro system technology wafer, and vapour penetration openings are forming starting from the side facing away from the system technology wafer, and wherein the production of the adjustment structures corresponding to the mask adjustment structures of the vapour penetration mask in location and shape, in the micro system technology wafer is affected by etching of depressions which are formed starting from the surface to be provided with a deposition by means of a corresponding masking step and the same plasma mechanical etching method as with the vapour penetration mask.

17. Method according to claim 1, wherein the production of the at least two mask adjustment structures formed from the side facing the surface of the micro system technology wafer of the vapour penetration mask in a combined disc out of silicon and glass as protruding structure by means of a mask process using a protective mask on the back side and subsequent material removal, wherein by means of a time-controlled removal, cone-shaped protrusions are forming on the side facing the micro system technology wafer and the vapour penetration openings starting from the side facing away from the micro system technology wafer, wherein the production of the adjustment structures corresponding to the mask adjustment structures of the vapour penetration mask in position and size, in the micro system technology wafer by material removal in the shape of depressions which are formed, starting from the surface to be provided with a deposition, with a corresponding masking process and the same removal method as with the vapour penetration mask.

18. Method according to claim 1, wherein the production of the at least two mask adjustment structures formed from the side facing the surface of the micro system technology wafer of the vapour penetration mask in a combined disc out of silicon and glass as protruding structures by means of a mask process using a protective mask on the back side and subsequent material removal, wherein by means of a time-controlled removal, cone-shaped protrusions are forming on the side facing the micro system technology wafer and the vapour penetration openings starting from the side facing away from the micro system technology wafer, wherein the production of the adjustment structures corresponding to the mask adjustment structures of the vapour penetration mask in position and size, in the micro system technology wafer by material removal in the shape of depressions which are made starting from the surface to be coated with the corresponding masking process and the same removal method which was used in the formation of the mask adjustment structures of the vapour penetration mask.

19. Method according to claim 18, wherein for forming the adjustment structures and the mask adjustment structures, on the one hand, and the vapour penetration openings, on the other hand, different removal methods are used which are selected from the group of: KOH etching, plasma mechanical etching, micro milling, micro boring, sandblasting.

20. Method according to claim 18, wherein for formation of the adjustment structures and the mask adjustment structures, on the one hand, and the vapour penetration openings, on the other hand, the same removal processes are used each selected from the group: micro milling, micro boring, sandblasting.

21. Method for the selective material deposition on a micro system technology wafer using a vapour penetration mask and having adjustment structures between the wafer of the micro system technology and the mask, comprising the steps:
forming at least two adjustment structures on the micro system technology wafer using a defined structuring technology;
forming at least two essentially complementary mask adjustment structures on a mask disk which has the same diameter as the wafer of the micro system technology, wherein the formation of the adjustment structure is affected using the same structuring technology;
inserting vapour penetration openings in the mask disc for forming the vapour penetration mask, wherein the vapour penetration openings leave defined areas of the wafer at the selective material deposition open upon self-adjusting positioning the vapour penetration mask on the wafer of the micro system technology, for a selective material deposition on the micro system technology wafer through the vapour penetration openings of the mask.

22. Method according to claim 21, the vapour penetration mask is removed.

23. Method according to claim 21, wherein the formation of the adjustment structures corresponding to the mask adjustment structures of the vapour penetration mask in position and size, in the micro system technology waver is affected by etching the depressions and is affected starting from the surface to be coated, with a corresponding masking step and the same plasma mechanical etching method as with the vapour penetration mask.

24. Kit of parts out of a micro system technology wafer and a vapour penetration mask for the (highly) accurate, selective material deposition by means of adjustment structures on the vapour penetration mask and the micro system technology wafer, comprising
at least two protruded or depressed adjustment structures on the micro system technology wafer, generated using a predetermined structuring technology;
at least two essentially complementary, protruded or depressed mask adjustment structures on the mask disc which has the same diameter as the micro system technology wafer, using the predetermined structuring technology;
vapour penetration openings in the mask disc in order to produce a vapour penetration mask, wherein the vapour penetration openings allow to leave defined areas of the micro system technology wafer open for the selective material deposition.

25. (canceled)

26. Kit of parts according to claim 24, wherein the parts (components) are associated with each other as a set (kit) as mask and wafer having together a self-centring effect or ability, and notably not only in the assembled condition.

27. Kit of parts according to claim 24, wherein the protruded or depressed adjustment structures are provided on the surface side of the wafer and the mask.

28. Kit of parts according to claim 24, wherein the slope angle at the adjustment structures are provided as protrusions or depressions, which angles are matching to each other for assisting the centring affect.

29. Kit of parts according to claim 28, wherein the slope angle comprises between 50° and 70°.
